(19) United States
(12) Patent Application Publication
(10) Pub. No.: US 2025/0362343 A1
(43) Pub. Date: Nov. 27, 2025

(54) BUILT-IN SELF-TEST DEVICE AND ERROR DETECTION METHOD

(71) Applicant: Winbond Electronics Corp., Taichung City (TW)

(72) Inventors: Lih-Wei Lin, Hsinchu City (TW); Shao Hua Liu, Taoyuan City (TW); Chi Chang Yang, Hsinchu (TW)

(73) Assignee: Winbond Electronics Corp., Taichung City (TW)

(21) Appl. No.: 19/067,999

(22) Filed: Mar. 3, 2025

(30) Foreign Application Priority Data
May 22, 2024 (TW) 113118935

(51) Int. Cl. G01R 31/317

(52) U.S. Cl. CPC G01R 31/31724; G01R 31/31721

(57) ABSTRACT

A built-in self-test (BIST) device and an error detection method are provided. The BIST device is for fuse intellectual properties (IPs). The BIST device includes at least one fuse element, a computing circuit, a power supply circuit, and a processor. Each fuse element corresponds to the fuse IPs and provides a corresponding fuse bit value, and each fuse element further includes a check bit for providing a check bit value. The processor controls the computing circuit to obtain the fuse bit values and the check bit value from the at least one fuse element, and performs a logical operation based on the fuse bit values and the check bit value to generate a check result. The check result is used to indicate whether a blown error occurs in the at least one fuse element.

### CROSS-REFERENCE TO RELATED APPLICATION

This application claims the priority benefit of Taiwan application serial no. 113118935, filed on May 22, 2024. The entirety of the above-mentioned patent application is hereby incorporated by reference herein and made a part of this specification.

### BACKGROUND

### Technical Field

The disclosure relates to a technology for detecting fuse intellectual properties (IPs) or fuse application in a semiconductor device, and particularly relates to a built-in self-test device and an error detection method.

### Description of Related Art

Fuse IPs or fuse applications are often used in semiconductor technology and very large-scale integrated circuit (VLSI) applications, for example, in a system on a chip (SoC), digital or analog integrated circuits (ICs), memory ICs or similar devices. Since a chip may need fine-tuning after manufacturing due to factors such as correction of process drift, signal drift, application requirements, configuration calibration, chip identification code, etc., fuses and related fuse elements may be pre-set in the chip, and the corresponding fuse elements may be enabled/disabled through the fuses. However, handling of fuses still has a probability of blown error, and it is difficult to easily determine from the outside whether the handling of these fuses meets operator's expectations.

A current method of detecting fuses mainly adopts a dumping test that detects one bit at a time. However, as the accumulation of semiconductors increases, a number of fuse bits currently used is relatively large, so that it will be very time consuming if the dumping test is adopted. Moreover, each fuse has a different usage purpose, and users need to read a fuse file corresponding to an initial design of the chip in order to learn an original configuration status of each fuse. Therefore, how to effectively test a result of the treated fuses is one of the problems to be solved in the fuse applications.

### SUMMARY

The disclosure is directed to a built-in self-test device and an error detection method, which are adapted to simultaneously check whether multiple fuse elements have blown errors, thereby reducing an inspection time of fuses, and adopt corresponding tests in a built-in self-test (BIST) technology to increase multi-faceted detection of the fuse elements.

An embodiment of the disclosure provides a built-in self-test (BIST) device for fuse intellectual properties (IPs). The BIST device includes at least one fuse element, a check bit, a computing circuit, a power supply circuit, and a processor. Each fuse element corresponds to the fuse IPs and provides corresponding at least one fuse bit value, and each fuse element further includes a check bit for providing a check bit value. The computing circuit is coupled to the at least one fuse element. The power supply circuit is controlled by the processor to provide power to the at least one fuse element. The processor is coupled to the computing circuit. The processor controls the computing circuit to obtain the fuse bit values and the check bit value from the at least one fuse element, performs a logical operation based on the fuse bit values and the check bit value to generate a check result. The check result is used to indicate whether a blown error occurs in the at least one fuse element.

An embodiment of the disclosure provides an error detection method for fuse intellectual properties (IPs). The error detection method includes: obtaining at least one fuse bit value and a check bit value from at least one fuse element, where each fuse element corresponds to the fuse IPs and provides the corresponding at least one fuse bit value, and each fuse element further includes a check bit to provide the check bit value; performing a logical operation based on the fuse bit values and the check bit value to generate a check result; and determining whether the at least one fuse element has a blown error based on the check result.

### BRIEF DESCRIPTION OF THE DRAWINGS

FIG. 1 is a schematic diagram of an electronic device having a built-in self-test (BIST) device according to a first embodiment of the disclosure.

FIG. 2 is a schematic diagram of fuse bit values of fuse elements, a check bit value, and a first logical result in FIG. 1.

FIG. 3 is a schematic diagram of an electronic device having a BIST device according to a second embodiment of the disclosure.

FIG. 4 is a flowchart of an error detection method according to the first and second embodiments of the disclosure.

FIG. 5 is a flowchart of a voltage shock test based on an error detection method according to an embodiment of the disclosure.

FIG. 6 is a schematic flowchart of an internal voltage and corresponding steps in FIG. 5.

### DESCRIPTION OF THE EMBODIMENTS

In order to perform fuse detection more efficiently and make a test result more accurate, embodiments of the disclosure add a check bit so that the check bit participates in encoding of fuse elements for testing (for example, built-in self-test (BIST) or design for testability (DFT)). The aforementioned test may be a parity check or other corresponding error correction logical operations, such as a cyclic redundancy check (CRC). Moreover, the embodiment may also adopt other tests in BIST technology for the fuse elements, such as a voltage shock test, a step-down shmoo test, a step-up shmoo test, etc., to increase multi-faceted detection of the fuses.

In detail, a plurality of embodiments of the disclosure add a check bit to each fuse element in a fuse box to detect whether a plurality of fuses in the fuse elements are successfully blown, thereby serving as a fuse fault detection. Therefore, the method of the embodiment of the disclosure may determine whether configuration statuses of the fuses are correct without reading a fuse file (which contains preset values of each fuse element) corresponding to an initial design of the chip. Moreover, the embodiment of the disclosure further adds additional related circuits for error correction to avoid a situation where an even number of fuses have blown errors, which may cause the embodiment of the disclosure to be unable to perform fault detection correctly. Multiple embodiments consistent with the disclosure are proposed below for illustrative descriptions.

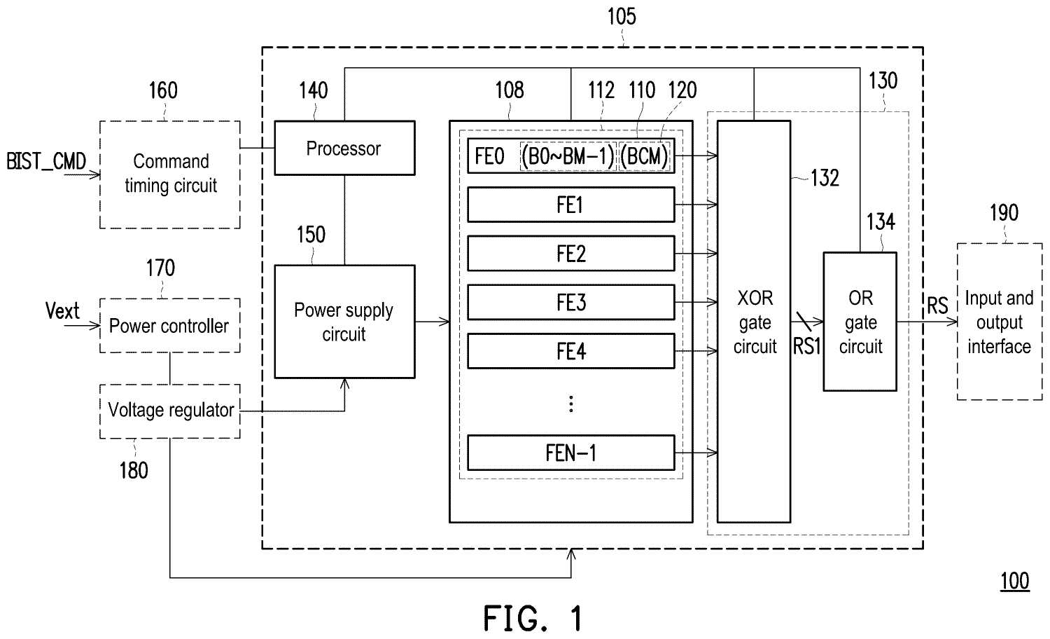

FIG. 1 is a schematic diagram of an electronic device 100 having a built-in self-test (BIST) device 105 according to a first embodiment of the disclosure. The electronic device 100 is a semiconductor device, and the electronic device 100 may be a SoC, a digital or analog integrated circuit, a volatile memory device, a non-volatile memory device, or a corresponding device. The electronic device 100 may include the BIST device 105, a command timing circuit 160, a power controller 170, a voltage regulator 180, and an input and output interface 190.

The BIST device 105 is used for fuse IPs (or fuse application). The BIST device 105 includes at least one fuse element 110 (corresponding to fuse elements FE0 to FEN-1 in FIG. 1), a computing circuit 130, a power supply circuit 150, and a processor 140. The processor 140 controls the computing circuit 130 to obtain fuse bit values 112 (which are also known as fuse bit values B0 to BM-1) and a check bit value BCM from the fuse elements FE0 to FEN-1, and perform logical operations based on the corresponding fuse bit values B0 to BM-1 in each fuse element (for example, the fuse element FE0) and the check bit value BCM corresponding to a check bit 120 to generate a check result RS. The check result RS is used to indicate whether there is a blown error in the fuse elements FE0 to FEN-1. Here, the fuse bit values B0 to BM-1 in each fuse element are set to 8 bits, i.e., M is equal to 8, for convenience of explanation. Those who apply this embodiment may adjust the value of M according to their needs.

The fuse elements FE0 to FEN-1 correspond to the same or different fuse IPs. For example, a fuse IP may correspond to the fuse element FE0, and the fuse element FE0 includes the fuse bit values B0 to BM-1. Another type of fuse IP may correspond to the fuse elements FE1 to FE3, and each of the fuse elements FE1 to FE3 includes 8 different fuse bit values. The fuse elements FE0 to FEN-1 may enable/disable the corresponding fuse IPs. The fuse IPs may include enabling or disabling of applications such as chip configuration settings, redundant components, maintenance components, mixed signal configuration settings, input and output interface fine-tuning, phase-locked loops (PLL), power supply configuration, chip identification codes, etc., which may be achieved by those skilled in the art by using suitable fuse IPs according to their needs.

The first embodiment takes 8 fuse elements (i.e., N is 8 in FIG. 1, the fuse elements FE0 to FE7) and the corresponding fuse bit values as an example for description. Those who apply this embodiment may adjust the number of the fuse elements according to their actual needs, or use the eight fuse elements FE0 to FE7 in the first embodiment as a fuse box 108, and implement the embodiment through multiple groups of fuse boxes. The fuse element in the embodiment may be a one-time programming (OTP) or multiple-time programming (MTP) metal fuse, an electronic fuse (efuse), etc., and those who apply this embodiment are not limited by material and element types of the fuse elements. The fuse box 108 in the embodiment is composed of N fuse elements (the fuse elements FE0 to FEN-1) and a check bit 120. The “data code” described in the embodiment is formed by the fuse bit values B0 to BM-1 corresponding to each of the fuse elements FE0 to FE7 plus the check bit value BCM corresponding to the check bit 120, so that the data code corresponding to each of the fuse elements FE0 to FE7 has 9 bits.

Each of the fuse elements FE0 to FE7 may provide the corresponding fuse bit values B0 to BM-1. Each of the fuse bit values B0 to BM-1 may indicate whether the corresponding M-bit fuses in the fuse elements FE0 to FE7 are blown (in the embodiment, M is, for example, 8). Not necessarily every fuse bit value B0 to BM-1 will be blown, but the fuse bit values B0 to BM-1 in the fuse elements FE0 to FE7 will be selectively blown according to the needs of the user of the embodiment. In other words, the fuse bit values B0 to BM-1 in the fuse elements FE0 to FEN-1 respectively have a preset fuse bit value.

The check bit 120 is used to provide the check bit value BCM. In the embodiment, the value of the check bit value BCM in the check bit 120 is set based on the preset fuse bit value corresponding to the specific fuse element (for example, the fuse element FE0). For example, taking odd parity bit check as an example, if the preset fuse bit value corresponding to the fuse element FE0 has an even number of “1s”, the check bit value BCM in the check bit 120 is then set to “0”; if the preset fuse bit value corresponding to the fuse element FE0 has an odd number of “1s”, the check bit value BCM in the check bit 120 is set to “1”.

The first embodiment is to present the BIST device 105 for implementing odd parity bit check, so that the computing circuit 130 includes an XOR gate circuit 132 and an OR gate circuit 134. The XOR gate circuit 132 is coupled to the fuse elements FE0 to FEN-1 to perform XOR operations based on the fuse bit values of each of the fuse elements FE0 to FEN-1 and the check bit value to generate a first logical result RS1. The fuse bit values of each of the fuse elements FE0 to FEN-1 and the check bit value respectively produce one first logical result RS1 based on the XOR operation of the XOR gate circuit 132. The XOR operation may produce an output of “1” when the number of “1s” in the 9-bit data code of each fuse element is an odd number, indicating that the fuse element FE0 has a blown error, and may produce an output of “0” to serve as the first logical result RS1 when the number of “1s” in the 9-bit data code of each fuse element is an even number, indicating that the fuse element should have no blown error.

The OR gate circuit 134 is coupled to the XOR gate circuit 132. The OR gate circuit 134 is configured to generate a check result RS based on the first logical results RS1. In detail, each fuse element in the BIST device 105 correspondingly generates one first logical result RS1, so that the first logical results RS1 correspond to the number of the fuse elements. The OR gate circuit 134 may perform an OR operation on these first logical results RS1, and as long as one of the first logical results RS1 is “1”, the check result RS generated by the OR gate circuit 134 will be “1”, indicating that there is a blown error in the fuse elements FE0 to FEN-1. Only when each of the first logical results RS1 is “0”, the check result RS generated by the OR gate circuit 134 is “O”, indicating that there should be no blown error in the fuse elements FE0 to FEN-1.

The processor 140 of the embodiment further controls the computing circuit 130 and the power supply circuit 150 to perform various BIST tests on the fuse elements FE0 to FEN-1, such as voltage shock test, step-down shmoo test, step-up shmoo test, etc. These tests will be introduced in detail in the following embodiments. The processor 140 may receive a BIST command BIST_CMD through the external command timing circuit 160. The power supply circuit 150 obtains power from an external voltage Vext through the power controller 170 and the voltage regulator 180, and supplies power to the fuse elements FE0 to FEN-1. In detail, the power supply circuit 150 may be a BIST power logic circuit and a power generator. The power supply circuit 150 is controlled by the processor 140 to provide corresponding voltages to the fuse elements FE0 to FEN-1 according to the requirements of the various BIST tests mentioned above.

If the logical operation in the BIST device 105 in FIG. 1 is adjusted to a cyclic redundancy check (CRC), a plurality of check bits may be added to each of the fuse elements FE0 to FEN-1, and the computing circuit 130 may be adjusted to a corresponding logic circuit that complies with the CRC, so as to perform the CRC on the fuse bit values B0 to BM-1 in the fuse elements FE0 to FEN-1 based on multiple preset bit values in the check bits to learn whether the fuse elements FE0 to FEN-1 have blown errors through the check result RS generated after performing the CRC. For example, the check result RS is “0” (no blown error) or “1” (there is a blown error).

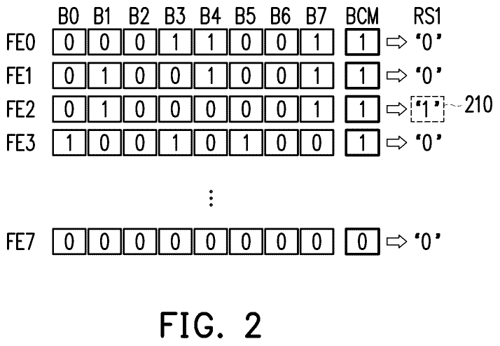

FIG. 2 is a schematic diagram of the fuse bit values of the fuse elements FE0 to FE7, the check bit value, and the first logical result in FIG. 1. Referring to FIG. 2, assuming that the data code in the fuse element FE0 is “000110011” (the fuse bit values B0 to BM-1 are “00011001”, and the check bit value BCM is “1”), which has 4 “1”, then the generated first logical result RS1 is “O”, which means that the fuse bit values in the fuse element FE0 are all correct and there are no blown errors, or there are two fuse elements having blown errors (which cannot be detected in the first embodiment). The data code in the fuse elements FE1, FE3, and FE7 and the first logical result RS1 may be deduced in the same way. On the other hand, assuming that the data code in fuse element FE2 is “010000011” (the fuse bit values B0 to BM-1 are “01000001”, and the check bit value BCM is “1”), which has 3 “1”, then the generated first logical result RS1 is “1” (as shown by a mark 210), indicating that one fuse has the blown error in the 8-bit fuses of the fuse element FE2.

It should be noted here that since a group of fuse elements in the first embodiment (such as one of the fuse elements FE0 to FEN-1 in FIG. 1) is usually controlled by a same fuse IP, it is rare that two or more fuses in a single group of the fuse elements have blown errors at the same time.

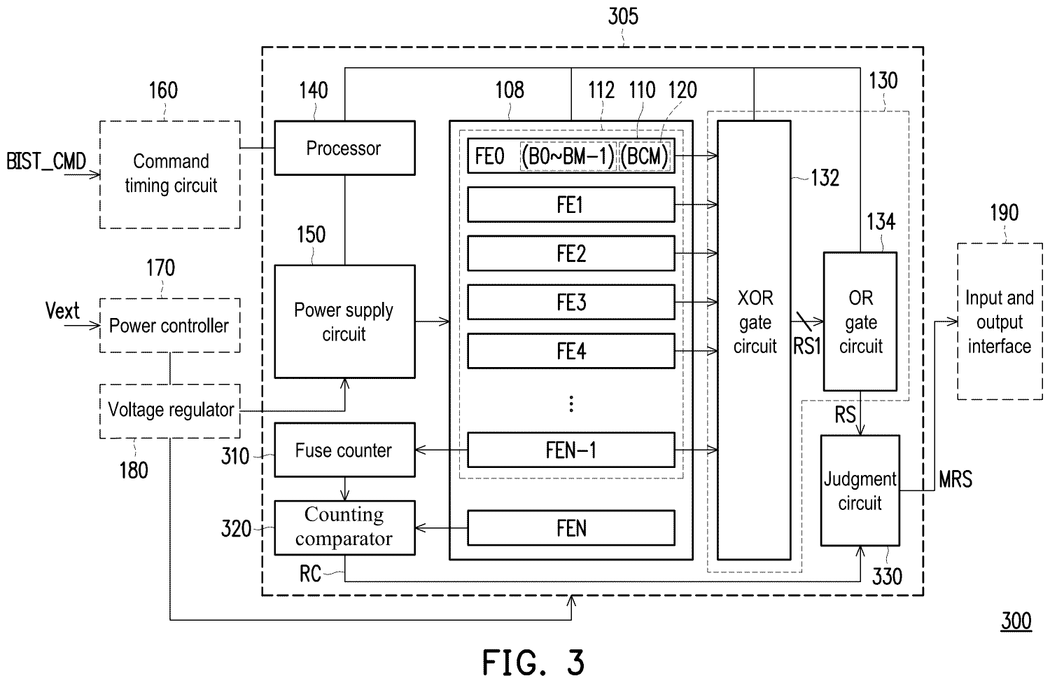

FIG. 3 is a schematic diagram of an electronic device 300 having a BIST device 305 according to a second embodiment of the disclosure. A difference from the first embodiment is that in the second embodiment, in addition to the components in FIG. 1, the BIST device 305 additionally adds circuits for error correction (such as a data fuse element FEN, a fuse counter 310, a counting comparator 320, and a judgment circuit 330 in FIG. 3), so that the embodiment of the disclosure may detect the situation where an even number of fuses in a single group of the fuse elements FE0 to FEN-1 have blown errors at the same time.

In detail, the data fuse element FEN is configured to record a preset accumulative value. The preset accumulative value is an accumulative total number of all fuse elements (for example, the fuse elements FE0 to FEN-1 in FIG. 3) whose corresponding preset fuse bit value is a first value (for example, “1”). Assuming that the accumulative total number is “32”, the data fuse element FEN may be expressed as an 8-bit “00100000”. The data fuse element FEN of the embodiment does not include a check bit. In other embodiments, the data fuse element FEN may also include a check bit like the fuse elements FE0 to FEN-1, and the computing circuit 130 may perform the same operation on the data fuse element FEN as the fuse elements FE0 to FEN-1 to determine whether the data fuse element FEN has a blown error.

The fuse counter 310 is coupled to the fuse elements FE0 to FEN-1. The fuse counter 310 is configured to count a number of the fuse elements FE0 to FEN-1 with the corresponding fuse bit values B0 to BM-1 being the first value (“1”) to generate a current accumulative value. The counting comparator 320 is coupled to the data fuse element FEN and the fuse counter 310. The counting comparator 320 is configured to compare whether the preset accumulative value in the data fuse element FEN is the same as the current accumulative value counted by the fuse counter 310 to generate a comparison result RC.

The judgment circuit 330 is coupled to the counting comparator 320 and the computing circuit 130. The judgment circuit 330 generates a comprehensive check result MRS based on the check result RS in the computing circuit 130 and the aforementioned comparison result RC. The comprehensive check result MRS is configured to indicate whether the fuses in the fuse elements FE0 to FEN-1 have blown errors. For example, when the check result RS indicates that the number of “1s” in the data code is an odd number, the comprehensive check result MRS generated by the 5 judgment circuit 330 should be “1” (there is a blown error); when the check result RS indicates that the number of “1s” in the data code is an even number, and the comparison result RC indicates that the aforementioned preset accumulative value is the same as the current accumulative value, it means that the corresponding fuses among the fuse elements FE0 to FEN-1 have no blown error, so that the comprehensive check result MRS generated by the judgment circuit 330 should be “0” (no blown error); when the check result RS indicates that the number of “1s” in the data code is an even number, but the comparison result RC indicates that the aforementioned preset accumulative value is not the same as the current accumulative value, it means that an even number of fuses corresponding to at least one group of fuse elements in the fuse elements FE0 to FEN-1 have blown errors, so that the comprehensive check result MRS generated by the judgment circuit 330 should be “1” (there is a blown error). The comprehensive check result MRS may be provided to the input and output interface 190, and an external user may perform corresponding compensation operations based on the comprehensive check result MRS, or decide whether to use or adjust the electronic device 300.

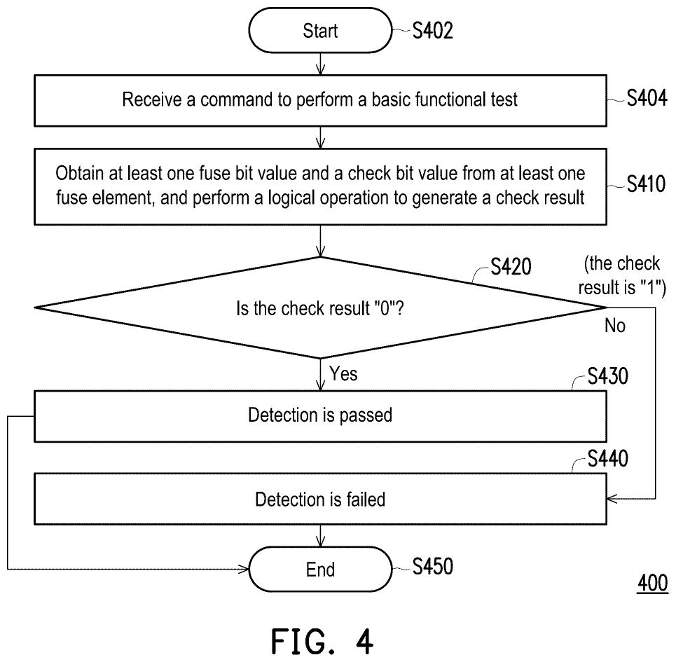

FIG. 4 is a flowchart of an error detection method 400 according to the first and second embodiments of the disclosure. The error detection method 400 is applicable to the BIST device 105 or the BIST device 305 of the aforementioned first or second embodiment. The first embodiment and FIG. 4 are used for description.

Referring to FIG. 1 and FIG. 4 at the same time, in step S402, the error detection method is started, for example, the BIST device 105 of FIG. 1 is activated. In step S404, the BIST device 105 receives a command to perform a basic functional test of the fuse elements. In step S410, the fuse bit values B0 to BM-1 and the check bit value BCM are obtained from the fuse elements FE0 to FEN-1, and a logical operation is performed by the computing circuit 130 to generate the check result RS. Each of the fuse elements FE0 to FEN-1 corresponds to the fuse IPs and provides the corresponding fuse bit values B0 to BM-1, and each of the fuse elements FE0 to FEN-1 further includes the check bit 120 to provide the check bit value BCM. If the logical operation is a parity check, in step S410, an XOR operation may be first performed based on the fuse bit values B0 to BM-1 in each of the fuse elements and the check bit value BCM to generate corresponding first logical results RS1, and then the check result RS is generated based on these first logical results RS1.

In step S420, it is determined whether the check result RS is “0”. If the check result RS is “0” (i.e., “Yes”), step S430 is entered from step S420, indicating that the detection is passed and each of the fuse elements FE0 to FEN-1 has no blown error. If the check result RS is “1” (i.e., “No”), step S440 is entered from step S420, indicating that the detection is failed, and there are fuses in the fuse elements FE0 to FEN-1 that have blown errors. After step S430 and step S440 are executed, step S450 is entered to end the error detection method.

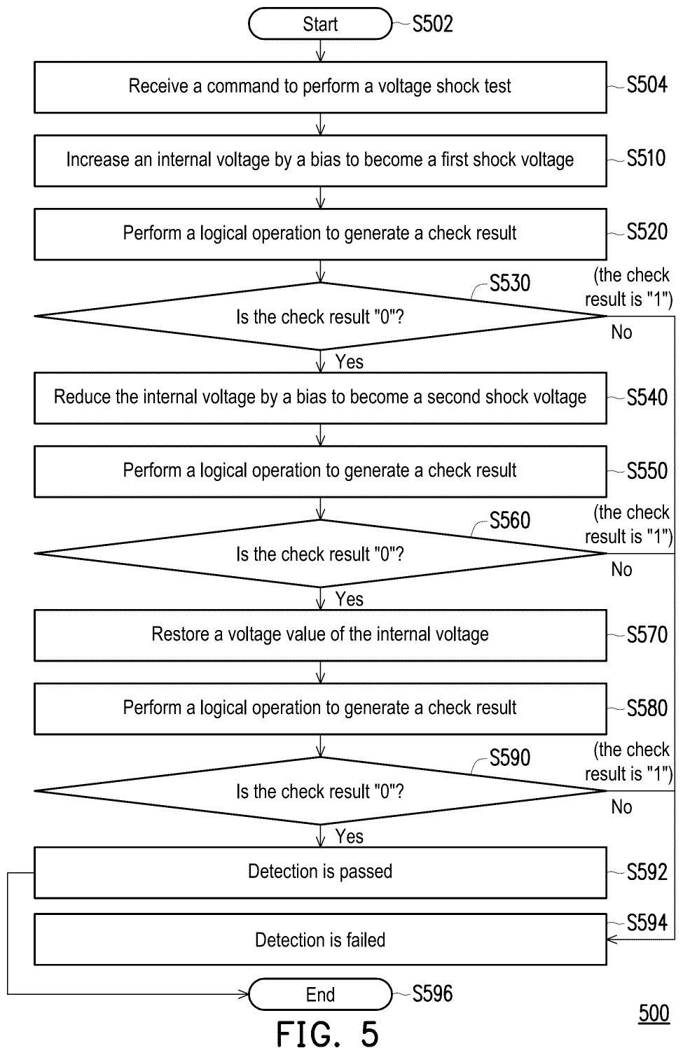

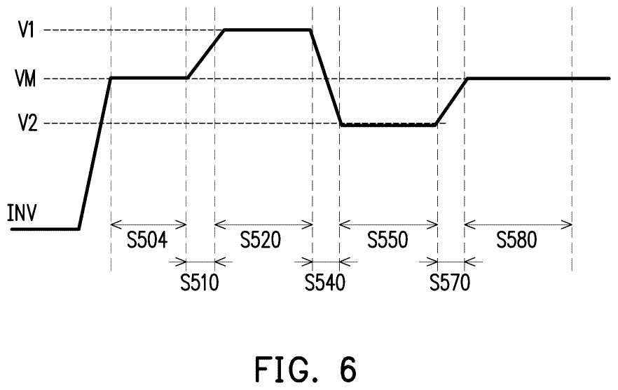

FIG. 5 is a flowchart of a voltage shock test based on an error detection method 500 according to an embodiment of the disclosure. FIG. 6 is a schematic flowchart of an internal voltage INV and corresponding steps in FIG. 5. The error detection method 500 is applicable to the BIST device 105 or the BIST device 305 of the aforementioned first or second embodiment. The first embodiment will be described with reference to FIG. 1, FIG. 5 and FIG. 6.

Referring to FIG. 1, FIG. 5 and FIG. 6 at the same time, in step S502, the error detection method is started, for example, the BIST device 105 is activated. In step S504, the BIST device 105 receives a command to perform a voltage shock test on the fuse elements. In step S510, the processor 140 controls the power supply circuit 150 to increase the internal voltage INV provided to the fuse elements FE0 to FEN-1 by a predetermined bias to become a first shock voltage V1. In step S520, the fuse bit values B0 to BM-1 and the check bit value BCM are obtained from the fuse elements FE0 to FEN-1 based on the first shock voltage V1, and a logical operation is performed through the computing circuit 130 to generate the check result RS.

In step S530, it is determined whether the check result RS is “0”. If the check result RS is “1” (i.e., “No”), step S594 is entered, indicating that the detection fails. If the check result RS is “0” (i.e., “Yes”), then step S540 is entered, and the processor 140 controls the power supply circuit 150 to reduce the internal voltage INV provided to the fuse elements FE0 to FEN-1 by a predetermined bias to become a second shock voltage V2. In step S520, the fuse bit values B0 to BM-1 and the check bit value BCM are obtained from the fuse elements FE0 to FEN-1 based on the second shock voltage V2, and a logical operation is performed through the computing circuit 130 to generate the check result RS.

In step S560, it is determined whether the check result RS is “0”. If the check result RS is “1” (i.e., “No”), step S594 is entered, indicating that the detection fails. If the check result RS is “O” (i.e., “yes”), then step S570 is entered, where the processor 140 controls the power supply circuit 150 to restore the internal voltage INV provided to the fuse elements FE0 to FEN-1 from the second shock voltage V2 to a voltage value VM of the internal voltage. In step S580, based on the voltage value VM of the internal voltage, the fuse bit values B0 to BM-1 and the check bit value BCM are obtained from the fuse elements FE0 to FEN-1, and a logical operation is performed by the computing circuit 130 to generate the check result RS.

In step S590, it is determined whether the check result RS is “0”. If the check result RS is “1” (i.e., “No”), step S594 is entered, indicating that the detection fails. If the check result RS is “0” (i.e., “Yes”), step S592 is entered, indicating that the test is passed, and each of the fuse elements FE0 to FEN-1 has no blown error after taking the voltage shock test. After step S592 and step S594 are executed, step S596 is entered to end the error detection method.

FIG. 5 and FIG. 6 show a voltage shock test performed on the fuse elements by adjusting the internal voltage provided to the fuse elements, thereby determining whether the fuse bit values B0 to BM-1 in the fuse elements FE0 to FEN-1 still maintain the same values under different internal voltages. In addition, regarding the BIST test of the embodiment of the disclosure, a step-down shmoo test may be performed, where by gradually lowering the internal voltage provided to the fuse elements, it is determined whether the fuse bit values B0 to BM-1 in the fuse elements FE0 to FEN-1 still maintain the same values under different internal voltages. Alternatively, a step-up shmoo test may be performed, where by gradually increasing the internal voltage provided to the fuse elements, it is determined whether the fuse bit values B0 to BM-1 in the fuse elements FE0 to FEN-1 still maintain the same values under different internal voltages. In addition, the BIST test of the embodiment of the disclosure may also test and determine whether the fuse bit values B0 to BM-1 in the fuse elements FE0 to FEN-1 still maintain the same values under different external temperatures by adjusting an external temperature.

In summary, the BIST device and the error detection method described in the embodiment of the disclosure add a check bit to the fuse elements used for testing, and test the same simultaneously with the original fuse code bit to simultaneously check whether these fuse elements are successfully blown or have blown errors, thereby reducing an inspection time for the fuses. Moreover, the embodiment may also adopt the BIST technology to perform other tests on the fuse elements, such as a voltage shock test, a step-down shmoo test, a step-up shmoo test, etc., to increase multi-faceted detection of the fuse elements.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A built-in self-test device, adapted to fuse intellectual properties (IPs), and comprising:
at least one fuse element, each of the at least one fuse element corresponding to the fuse IPs and providing corresponding at least one fuse bit value, and each of the at least one fuse element further comprising a check bit for providing a check bit value;
a computing circuit, coupled to the at least one fuse element;
a power supply circuit, controlled by a processor to provide power to the at least one fuse element; and
the processor, coupled to the computing circuit,
wherein the processor controls the computing circuit to obtain the fuse bit values and the check bit value from the at least one fuse element, and performs a logical operation based on the fuse bit values and the check bit value to generate a check result,
wherein the check result is used to indicate whether a blown error occurs in the at least one fuse element.

2. The built-in self-test device as claimed in claim 1, wherein the logical operation is a parity check or a cyclic redundancy check,
wherein a value of the check bit value in the check bit is set based on a preset fuse bit value corresponding to the at least one fuse element.

3. The built-in self-test device as claimed in claim 1, wherein the computing circuit comprises:
an XOR gate circuit, coupled to the at least one fuse element, and configured to perform an XOR operation based on the fuse bit values and the check bit value in each of the at least one fuse element to respectively produce a first logical result; and
an OR gate circuit, coupled to the XOR gate circuit, and configured to generate the check result based on the first logical result.

4. The built-in self-test device as claimed in claim 1, wherein the processor further controls the computing circuit and the power supply circuit to perform one of a voltage shock test, a step-down shmoo test, and a step-up shmoo test on the at least one fuse element.

5. The built-in self-test device as claimed in claim 1, further comprising:
a data fuse element, configured to record a preset accumulative value, the preset accumulative value being an accumulative total number of all of the at least one fuse element with corresponding preset fuse bit values being a first value;
a fuse counter, coupled to the at least one fuse element, and configured to count a number of all of the at least one fuse element with the corresponding at least one fuse bit value being the first value to generate a current accumulative value;
a counting comparator, coupled to the fuse counter, and configured to compare whether the preset accumulative value in the data fuse element is the same as the current accumulative value to generate a comparison result; and
a judgment circuit, coupled to the counting comparator and the computing circuit, and configured to generate a comprehensive check result based on the check result in the computing circuit and the comparison result, wherein the comprehensive check result is used to indicate whether the at least one fuse element has the blown error.

6. An error detection method, adapted to fuse intellectual properties (IPs), and comprising:
obtaining at least one fuse bit value and a check bit value from at least one fuse element, wherein each of the at least one fuse element corresponds to the fuse IPs and provides the corresponding at least one fuse bit value, and each of the at least one fuse element further comprises a check bit to provide the check bit value;
performing a logical operation based on the fuse bit values and the check bit value to generate a check result; and
determining whether the at least one fuse element has a blown error based on the check result.

7. The error detection method as claimed in claim 6, wherein a value of the check bit value in the check bit is set based on a preset fuse bit value corresponding to the at least one fuse element.

8. The error detection method as claimed in claim 6, wherein the logical operation is a parity check,
wherein the step of performing the logical operation based on the fuse bit values and the check bit value to generate the check result comprises:
performing an XOR operation based on the fuse bit values and the check bit value in each of the at least one fuse element to respectively produce a first logical result; and
generating the check result based on the first logical result.

9. The error detection method as claimed in claim 6, further comprising:
counting a number of all of the at least one fuse element with the corresponding at least one fuse bit value being a first value to generate a current accumulative value;
comparing whether a preset accumulative value in a data fuse element is the same as the current accumulative value to generate a comparison result; and
generating a comprehensive check result based on the check result and the comparison result, wherein the comprehensive check result is used to indicate whether the at least one fuse element has the blown error.

10. The error detection method as claimed in claim 6, further comprising:
performing one of a voltage shock test, a step-down shmoo test, and a step-up shmoo test on the at least one fuse element.
